(19) United States
(12) Patent Application Publication
(10) Pub. No.: US 2026/0005131 A1
(43) Pub. Date: Jan. 1, 2026

(54) DEVICE, METHOD AND SYSTEM TO PROVIDE ELECTRICAL COUPLING ACROSS ACTIVE LAYERS OF AN INTEGRATED CIRCUIT DIE

(71) Applicant: Intel Corporation, Santa Clara, CA (US)

(72) Inventors: Abhishek Anil Sharma, Portland, OR (US); Sagar Suthram, Portland, OR (US); Pushkar Ranade, San Jose, CA (US); Wilfred Gomes, Portland, OR (US); Tahir Ghani, Portland, OR (US); Anand Murthy, Portland, OR (US)

(73) Assignee: Intel Corporation, Santa Clara, CA (US)

(21) Appl. No.: 18/759,339

(22) Filed: Jun. 28, 2024

(51) Int. Cl. H01L 23/522; H01L 21/768; H01L 23/528

(52) U.S. Cl. CPC H01L 23/5226; H01L 21/76877; H01L 23/5283

(57) ABSTRACT

Techniques and mechanisms for an integrated circuit (IC) die to provide electrical coupling across active layers. In an embodiment, an IC die comprises a first active layer, a second active layer, first metallization layers between the first and second active layers, and second metallization layers on the second active layer. A via structure extends through one or more of the second metallization layers, and further through the second active layer and the first metallization layers, to a side of the first active layer. The via structure is electrically coupled to a first interconnect structure of the second metallization layers and a second interconnect structure which is on an opposite side of the first active layer. In another embodiment, a distal end of the via structure adjoins multiple vias which each extend from the second interconnect structure and at least partially through the first active layer.

### BACKGROUND

### 1. Technical Field

This disclosure generally relates to integrated circuitry and more particularly, but not exclusively, to a via structure which facilitates electrical coupling across active layers of an integrated circuit die.

### 2. Background Art

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for ever-more capacity, however, is not without issue. The necessity to optimize the performance of each device becomes increasingly significant.

In the manufacture of integrated circuit devices, multi-gate transistors, such as tri-gate transistors, have become more prevalent as device dimensions continue to scale down. In conventional processes, tri-gate transistors are generally fabricated on either bulk silicon substrates or silicon-on-insulator substrates. In some instances, bulk silicon substrates are preferred due to their lower cost and because they enable a less complicated tri-gate fabrication process. In another aspect, maintaining mobility improvement and short channel control as microelectronic device dimensions scale below the 10 nanometer (nm) node provides a challenge in device fabrication.

As successive generations of integrated circuit technologies continue to scale in size, speed, and efficiency, there is expected to be an increasing premium placed on improvements to how integrated circuits are interconnected.

### BRIEF DESCRIPTION OF THE DRAWINGS

The various embodiments of the present invention are illustrated by way of example, and not by way of limitation, in the figures of the accompanying drawings and in which:

FIG. 1 shows a block diagram illustrating features of an integrated circuit die structure comprising a via structure which facilitates electrical coupling across multiple active layers according to an embodiment.

FIG. 2 shows a flow diagram illustrating features of a method to provide a via structure which spans one or more active layers of an IC die according to an embodiment.

FIG. 3 shows a cross-sectional side view of an integrated circuit system comprising a via structure which extends through one or more active layers according to an embodiment.

FIG. 4 shows a cross-sectional side view of an integrated circuit system which facilitates electrical coupling across multiple active layers according to an embodiment.

FIGS. 5A through 5G show various cross-sectional side views of structures each during a respective stage of processing to fabricate an integrated circuit die according to an embodiment.

FIG. 6 illustrates a cross-sectional view of an integrated circuit die comprising via structures according to an embodiment.

FIG. 7 illustrates a diagram of an example data server machine employing an IC die with a via structure according to an embodiment.

FIG. 8 is a block diagram of an example computing device according to an embodiment.

### DETAILED DESCRIPTION

Embodiments discussed herein variously provide techniques and mechanisms for an integrated circuit (IC) die to provide electrical coupling across multiple active layers. In various embodiments, an IC die structure comprises a vertically stacked arrangement of a plurality of layers which each comprise respective non-linear (or “active”) circuit components, such as transistors, diodes and/or the like. A given one such layer (referred to as an “active layer”, or a “device layer”) is coupled to another such active layer via first metallization layers, interconnect structures of which facilitate electrical coupling of circuits in a single active layer, circuits in different respective active layers, and/or circuits which are external to said active layers. In one such embodiment, a via structure of the IC die extends, through the first metallization layers and the second active layer, to each of the first active layer and another metallization layer. In an embodiment, the via structure facilitates electrical coupling across both the first active layer and the second active layer—e.g., wherein the via structure further extends through the first active layer. In some embodiments, one distal end of the via structure lands in or on a first side of the active layer, and extends to a plurality of other via structures which each extend through some or all of the first active layer to an opposite side thereof.

The description herein includes numerous details to provide a more thorough explanation of the embodiments of the present disclosure. It will be apparent to one skilled in the art, however, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate a greater number of constituent signal paths, and/or have arrows at one or more ends, to indicate a direction of information flow. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, or magnetic connection between the things that are connected or an indirect connection, through one or more passive or active intermediary devices. The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

It is to be understood that the terms so used are interchangeable under appropriate circumstances such that the embodiments of the invention described herein are, for example, capable of operation in other orientations than those illustrated or otherwise described herein.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

The terms “left,” “right,” “front,” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. It is pointed out that those elements of a figure having the same reference numbers (or names) as the elements of any other figure can operate or function in any manner similar to that described, but are not limited to such.

In addition, the various elements of combinatorial logic and sequential logic discussed in the present disclosure may pertain both to physical structures (such as AND gates, OR gates, or XOR gates), or to synthesized or otherwise optimized collections of devices implementing the logical structures that are Boolean equivalents of the logic under discussion.

Here, multiple non-silicon semiconductor material layers may be stacked within a single fin structure. The multiple non-silicon semiconductor material layers may include one or more “P-type” layers that are suitable (e.g., offer higher hole mobility than silicon) for P-type transistors. The multiple non-silicon semiconductor material layers may further include one or more one or more “N-type” layers that are suitable (e.g., offer higher electron mobility than silicon) for N-type transistors. The multiple non-silicon semiconductor material layers may further include one or more intervening layers separating the N-type from the P-type layers. The intervening layers may be at least partially sacrificial, for example to allow one or more of a gate, source, or drain to wrap completely around a channel region of one or more of the N-type and P-type transistors. The multiple non-silicon semiconductor material layers may be fabricated, at least in part, with self-aligned techniques such that a stacked CMOS device may include both a high-mobility N-type and P-type transistor with a footprint of a single transistor.

For purposes of the embodiments, the transistors in various circuits, modules, and logic blocks are Tunneling FETs (TFETs). Some transistors of various embodiments may comprise metal oxide semiconductor (MOS) transistors, which include drain, source, gate, and bulk terminals. The transistors may also include Tri-Gate and FinFET transistors, Gate All Around Cylindrical Transistors, Square Wire, or Rectangular Ribbon Transistors or other devices implementing transistor functionality like carbon nanotubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors-BJT PNP/NPN, BICMOS, CMOS, etc., may be used for some transistors without departing from the scope of the disclosure.

The technologies described herein may be implemented in one or more electronic devices. Non-limiting examples of electronic devices that may utilize the technologies described herein include any kind of mobile device and/or stationary device, such as cameras, cell phones, computer terminals, desktop computers, electronic readers, facsimile machines, kiosks, laptop computers, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. More generally, the technologies described herein may be employed in any of a variety of electronic devices including an IC die which comprises a via structure that spans at least one active layer.

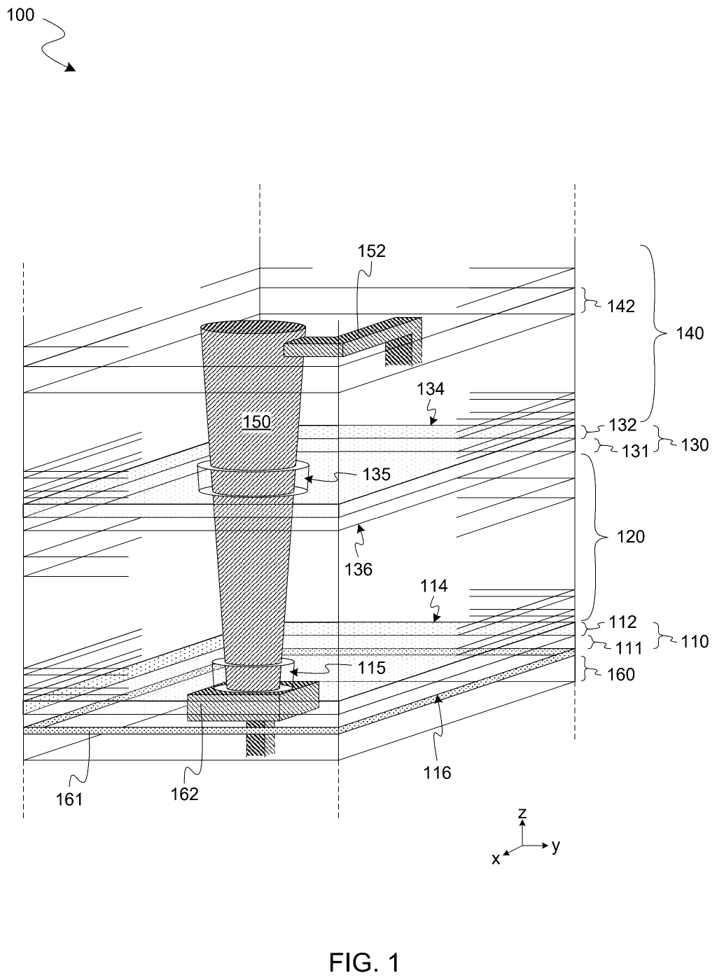

FIG. 1 shows features of an IC die structure 100 comprising a via structure which facilitates electrical coupling across multiple active layers according to an embodiment. IC die structure 100 illustrates one example of an embodiment wherein a via structure extends through one or more active layers of an IC die, wherein the via structure an electrical path across multiple active layers includes the via structure.

As shown in FIG. 1, IC die structure 100 comprises lateral surfaces each along a respective x-y plane that may be defined or taken at any vertical position of IC die structure 100. The lateral surface of the x-y plane is orthogonal to a vertical or build-up dimension as defined by the z-axis. In some embodiments, IC die structure 100 may be formed from, or on, any of various substrate materials—e.g., comprising the illustrative semiconductor layer 111 shown-which are suitable for the fabrication of transistors, diodes and/or other such active (or other) circuit components. In some embodiments, semiconductor layer 111 is used to manufacture circuit components 112 which, for example, include any of various suitable transistors, diodes, or the like of IC die structure 100. The semiconductor layer 111 may include that of a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 1, IC die structure 100—such as a monolithic IC structure or a composite IC structure-comprises multiple active layers which are in a stacked configuration with each other. In an embodiment, IC die structure 100 further comprises metallization layers which are variously disposed each between a respective two of the active layers, on a topmost one of the active layers, or (for example) under a bottommost one of the active layers.

In the example embodiment shown, an active layer 110 of IC die structure 100 comprises semiconductor layer 111 and circuit components 112, structures of which are variously formed in or on semiconductor layer 111. By way of illustration and not limitation, circuit components 112 comprise any of various suitable metal oxide semiconductor field effect transistors (MOSFETs) including one or more types of planar transistors and/or one or more types of non-planar transistors (such as tri-gate transistors, gate-all-around transistors, or the like).

In an embodiment, IC die structure 100 further comprises metallization layers 120 which are disposed on a back side of active layer 110. As used herein, the term “metallization layer” describes layers with interconnections or wires that provide electrical routing, generally formed of metal or other electrically and thermally conductive material. For example, interconnect structures of metallization layers 120 are to variously facilitate electrical coupling between circuits of active layer 110 and/or between other circuits which are to operate with active layer 110.

In one such embodiment, another active layer 130 of IC die structure 100 comprises a semiconductor layer 131 and circuit components 132, structures of which are variously formed in or on semiconductor layer 131. By way of illustration and not limitation, circuit components 112 comprise any of various suitable MOSFETs including planar transistors, non-planar transistors, and/or the like. In various embodiments, one active layer of IC die structure 100 comprises transistors of a memory array—e.g., wherein another active layer of IC die structure 100 of comprises transistors of another memory array, and/or comprises peripheral circuit logic (such as sense amplifiers, driver circuits, or the like) which facilitates access to one or more memory arrays. However, some embodiments are not limited regarding a particular functionality which is provided with a given one or more active layers of IC die structure 100.

In an embodiment, active layers 110, 130 are vertically stacked with each other—e.g., wherein metallization layers 120 and a portion of semiconductor layer 131 are disposed between circuit components 132 and active layer 110. Furthermore, IC die structure 100 comprises other metallization layers 140 which are disposed on a back side of active layer 130. For example, interconnect structures of metallization layers 140 are to variously facilitate electrical coupling between circuits of active layer 130, between respective circuits of active layers 110, 130, and/or with other circuitry of IC die structure 100. Further still, one or more additional (e.g., front-side) metallization layers—e.g., comprising the illustrative metallization layer 160 shown—are disposed under semiconductor layer 111. In one such embodiment, the one or more additional metallization layers include interconnect structures—e.g., comprising an interconnect structure 162 of metallization layer 1600—which are variously coupled electrically to other circuitry of IC die structure 100. In an embodiment, a dielectric layer 161 provides at least partial electrical insulation between the one or more additional metallization layers and circuit components 112.

To facilitate power delivery and/or other electrical coupling functionality, IC die structure 100 further comprises a via structure 150 which spans a region between two active layers, and which extends through at least one such active layer. In some embodiments, via structure 150 comprises one or more electrically conductive materials, such as copper and/or any of various suitable alloys thereof.

In the example embodiment shown, via structure 150 comprises a main body portion which extends along a vertical (z-axis) direction though active layer 130—e.g., as well as through metallization layers 120 and through at least some of metallization layers 140—to at least a side 114 of active layer 110. For example, via structure 150 extends to a level (in this case, a vertical height) of one or more structures of circuit components 112 and/or to a level of a dielectric material which adjoins such one or more structures of circuit components 112. In an embodiment, via structure 150 further extends at least partially into the vertical span of circuit components 112 and, in some embodiments, into the vertical span of (e.g., through) semiconductor layer 111. In various embodiments, the main body portion is, in one vertical cross-section, symmetric about a vertical centerline.

In various embodiments, via structure 150 extends vertically (in a z-axis direction) through a portion of a given active layer, and is surrounded in a horizontal (x-y) plane by said portion of the given active layer. In one such embodiment, via structure 150 is electrically insulated, at least partially, by a surrounding portion of the given active layer. Alternatively or in addition, via structure 150 is thermally insulated, at least partially, by the surrounding portion of the given active layer.

In the example embodiment shown, via structure 150 extends through a region 135 between opposite sides side 134, 136 of active layer 130. In some embodiments, a dielectric material (and/or a semiconductor material) in region 135 facilitates electrical insulation of via structure 150 at least between sides 134, 136—e.g., wherein any electrical coupling of via structure 150 to another conductive structure is outside of region 135. In some embodiments, via structure 150 further extends through another region 115 between opposite sides side 114, 116 of active layer 110. In one such embodiment, a dielectric material in region 115 facilitates electrical insulation of via structure 150 at least between sides 114, 116.

In some embodiments, via structure 150 is electrically coupled to one or more circuit structures of IC die structure 100. For example, in various embodiments, via structure 150 comprises a metal (e.g., copper) and is electrically coupled to two more interconnect structures each in a respective one of metallization layers 120, metallization layers 140 and metallization layer 160. In one such embodiment, via structure 150 is electrically coupled to each of a first interconnect structure of metallization layer 160, a second interconnect structure of metallization layers 120, and a third interconnect structure of metallization layers 140. In the example embodiment shown, via structure 150 extends to be electrically coupled to an interconnect structure 152 which is in a metallization layer 142 of the metallization layers 140 above active layer 130. Furthermore, via structure 150 extends through active layer 110, past an opposite side 116 thereof, to land on the interconnect structure 162 of metallization layer 160. In an alternative embodiment, via structure 150 instead extends only partially toward metallization layer 160—e.g., wherein a plurality of other via structures (not shown) variously extend each from interconnect structure 162, and at least partially through active layer 110, to be electrically coupled to a distal end of active layer 110.

In one such embodiment, via structure 150 is electrically coupled to facilitate power delivery to circuit components 112 and/or to circuit components 132 via metallization layers 120 and metallization layers 140. However, some embodiments are not limited with respect to a particular voltage and/or a particular signal which might be provided via via structure 150.

Although via structure 150 is shown as extending entirely through only one active layer—i.e., active layer 130—over active layer 110, in other embodiments, via structure 150 further extends through one or more other such active layers (not shown) of IC die structure 100. For example, in one such embodiment, another active layer of IC die structure 100 is over active layer 130 (but below metallization layer 142, for example), or is between active layer 130 and active layer 110.

In some embodiments, IC die structure 100 further comprises one or more additional via structures which variously have features similar to those of via structure 150. By way of illustration and not limitation, another such via structure (not shown) also extends from one of metallization layers 140—and through active layer 130 and the metallization layers 120—at least to (and for example, through) active layer 110, to facilitate electrical coupling with another interconnect structure of metallization layer 160.

In the example embodiment shown, a main body portion of via structure 150 tapers along the vertical (z-axis) distance between metallization layer 142 and side 114. By way of illustration and not limitation, a horizontal (x-y plane) dimension of such a main body portion at side 114 differs by at least 10% from a corresponding horizontal dimension of the main body portion at interconnect structure 152.

In an alternative embodiment, the main body portion of via structure 150 is substantially columnar along the entire vertical (z-axis) distance between semiconductor layer 111 and metallization layer 142. For example, a horizontal (x-y plane) dimension of such a main body portion at side 114 is, in one such embodiment, within 10% of a corresponding horizontal dimension of the main body portion at metallization layer 142.

Alternatively or in addition, in various embodiments, a cross-sectional dimension—e.g., an x-axis length or a y-axis width—of via structure 150 at a given height in metallization layers 120 (or in metallization layers 140, for example) is multiple times greater than a corresponding cross-sectional dimension of a via structure which also extends in the same given height. In one such embodiment, said cross-sectional dimension of via structure 150 is at least five times (and in some embodiments, at least ten times) the cross-sectional dimension of a via structure at the given height.

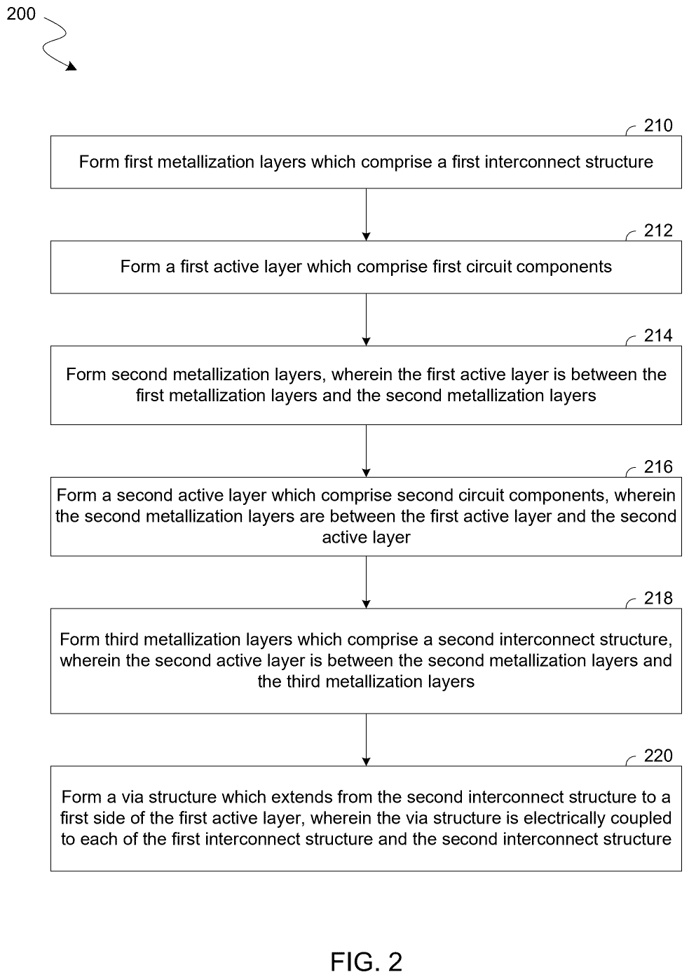

FIG. 2 shows a method 200 for providing a via structure of an IC die according to an embodiment. Method 200 illustrates one example of an embodiment which enables electrical coupling across multiple active layers of an IC die. Operations such as those of method 200 are performed to provide some or all of the functionality of IC die structure 100, for example.

As shown in FIG. 2, method 200 comprises (at 210) forming first metallization layers which comprise a first interconnect structure. In an illustrative embodiment, the first interconnect structure includes or otherwise corresponds functionally to metallization layer 160, for example. In an embodiment, the forming at 210 comprises forming one or more initial levels of patterned interconnect metallization structures which are variously embedded in, or otherwise insulated at least partially with, dielectric material structures. In an embodiment, the forming at 210 is adapted from conventional metallization techniques.

Method 200 further comprises (at 212) forming a first active layer which comprise first circuit components. For example, the forming at 210 comprises performing patterned mask, lithography, deposition and/or other suitable processes—e.g., adapted from conventional semiconductor fabrication techniques—to manufacture transistors (e.g., comprising metal oxide semiconductor field effect transistors, or “MOSFETs”), diodes and/or other active circuit components such as those of active layer 110. In an embodiment, the first circuit components are formed on a substrate comprising a first semiconductor material. By way of illustration and not limitation, the first semiconductor material comprises a monocrystalline semiconductor material such as, but not limited to, predominantly silicon (e.g., substantially pure Si) material, predominantly germanium (e.g., substantially pure Ge) material, or a compound material comprising a Group IV majority constituent (e.g., SiGe alloys, GeSn alloys). In various embodiments, the first semiconductor material is a Group III-N material comprising a Group III majority constituent and nitrogen as a majority constituent (e.g., GaN, InGaN). In another embodiment, the first semiconductor material is a Group III-V material comprising a Group III majority constituent and a Group IV majority constituent (e.g., InGaAs, GaAs, GaSb, InGaSb). In some embodiments, the forming at 210 is performed after formation of the first active layer at 212—e.g., wherein the patterned interconnect structures of the first metallization layers at least partially provide coupling of the first active circuit components with each other and/or with other circuitry.

Method 200 further comprises (at 214) forming second metallization layers on the first active layer—e.g., wherein such forming comprises operations similar to those performed at 210. The first active layer is between the first metallization layers and the second metallization layers—e.g., wherein the first active layer is proximate to the first metallization layers and/or to the second metallization layers.

Method 200 further comprises (at 216) forming a second active layer which comprise second circuit components (e.g., comprising other MOSFETs, diodes and/or other the like). The second metallization layers are between the first active layer and the second active layer—e.g., wherein the second metallization layers are adjacent to the first active layer and/or to the second active layer. In some embodiments, the second active layer is coupled to the second metallization layers via a hybrid bond process. In one such embodiment, the second active components are variously formed in or on a layer of a second semiconductor to provide a sub-assembly which is subsequently hybrid bonded (directly or indirectly) to the second metallization layers.

In another embodiment, the forming at 216 comprises depositing a layer of the second semiconductor material on the second metallization layers—e.g., via any of various suitable semiconductor layer transfer processes—and, subsequently, variously forming structures of the second circuit components in or on the second semiconductor material.

Method 200 further comprises (at 218) forming third metallization layers which comprise a second interconnect structure—e.g., wherein the second active layer is between the second metallization layers and the third metallization layers. In some embodiments, the third metallization layers adjoin the second active layer. Alternatively or in addition, method 200 further comprises forming one or more additional active layers and/or one or more additional metallization layers of the IC die, in some embodiments.

Method 200 further comprises (at 220) forming a via structure which extends from the second interconnect structure and at least to a first side of the first active layer. The via structure is electrically coupled to each of the first interconnect structure and the second interconnect structure—e.g., wherein the via structure extends to at least to the second interconnect structure. For example, the via structure extends vertically from the second interconnect structure, through one or more of the third metallization layers, and further through each of the second active layer and the second metallization layers.

In some embodiments, the via structure further extends vertically through the first active layer to the first interconnect structure. In one such embodiment, the via structure adjoins the first interconnect structure in a first (horizontal) plane, wherein a first contiguous cross-sectional area of the via structure in that first plane is less than eighty percent (and in some embodiments, less than fifty percent) of a second contiguous cross-sectional area of the first interconnect structure in the first plane.

In other embodiments, the via structure extends vertically to, but not into (or at least not entirely through), the first active layer. In one such embodiment, method 200 further comprises forming multiple vias which each extend from the first interconnect structure, and at least partially through the first active layer, to a distal end of the via structure. For example, formation of the multiple vias comprises operations which are adapted from conventional techniques for fabricating through-silicon via structures. In some embodiments, the via structure adjoins each of the multiple vias in a second (horizontal) plane, wherein a total of the respective cross-sectional areas of the multiple vias in the second plane is at least one third (and in some embodiments, at least one half) of a contiguous cross-sectional area of the via structure in that second plane.

The via structure extends to (and is electrically coupled with) each of the first interconnect structure of the first metallization layers and the second interconnect structures of the third metallization layers. In one such embodiment, the via structure further extends to, and is electrically coupled with, one or more other interconnect structures each of a respective one of the second metallization layers or the third metallization layers. Alternatively or in addition, the via structure further extends to, and is electrically coupled with, one or more other interconnect structures each of a respective one of other metallization layers of the IC die—e.g., wherein the via structure further extends though the other metallization layers and (for example) through one or more other active layers of the IC die.

In various embodiments, method 200 further comprises one or more other operations (not shown) to form an additional via structure of the IC die, similar to that which is formed at 220. In one such embodiment, the additional via structure is electrically coupled to each of a third interconnect structure of the first metallization layers, and a fourth interconnect structure of the third metallization layers. For example, the additional via structure extends vertically through one or more of the third metallization layers, and further through each of the second active layer and the second metallization layers, and at least to the first side of the first active layer. In various embodiments, the additional via structure further extends vertically through the first active layer to the third interconnect structure. In another embodiment, the additional via structure instead extends to multiple other vias which each extend from the third interconnect structure, and at least partially through the first active layer.

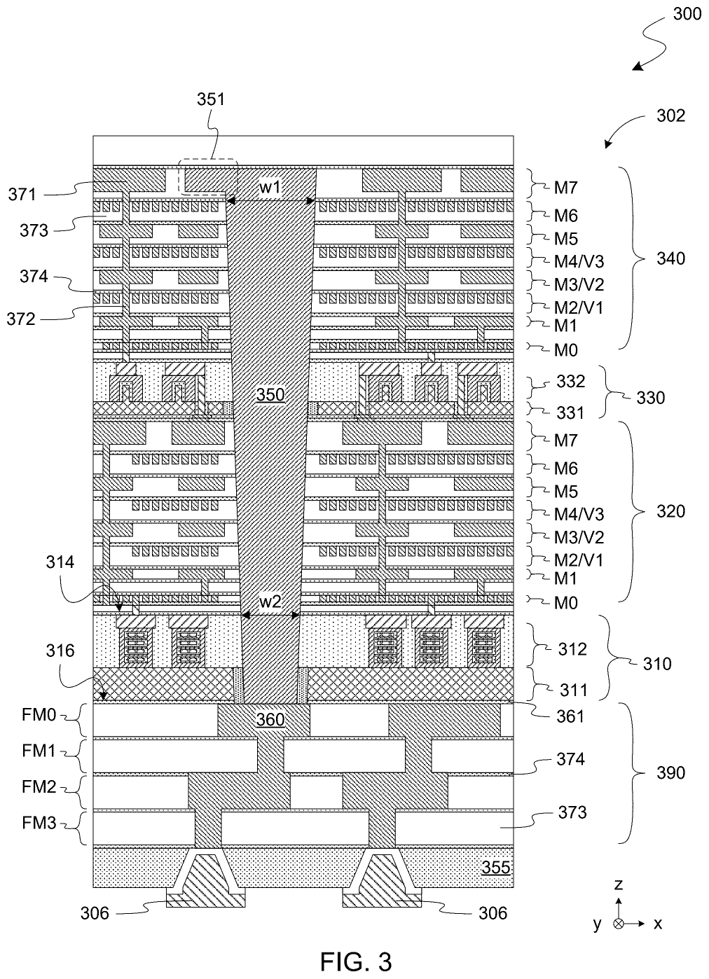

FIG. 3 shows features of an IC system 300 comprising a via structure which extends through one or more active layers according to an embodiment. In various embodiments, IC system 300 provides functionality such as that of IC die structure 100—e.g., wherein structures of IC system 300 are provided by one or more operations of method 200.

As shown in FIG. 3, IC system 300 includes an IC die 302, which is a monolithic (or alternatively, a composite) IC structure comprising multiple heterogeneous active layers which are vertically stacked in various respective arrangements with each other. In an embodiment, the IC structure of IC die 302 further comprises metallization layers which are variously disposed each between a respective two of the active layers, on a topmost one of the active layers, or (for example) under a bottommost one of the active layers.

In the example embodiment shown, IC die 302 comprises active layers 310, 330, metallization layers 320, and metallization layers 340, which correspond functionally to active layers 110, 130, metallization layers 120, and metallization layers 140 (respectively). Furthermore, additional metallization layers 390 of IC system 300 comprise a layer FM0 which (for example) corresponds functionally to metallization layer 160. Further still, IC die 302 comprises a via structure 350 which provides functionality such as that of via structure 150.

In the example embodiment shown, active layer 310 comprises a semiconductor layer 311 and circuit components 312 which are variously formed in or on semiconductor layer 311. Metallization layers 320 are disposed on a back side of active layer 310. Adjacent metallization layers, such as metallization interconnects 371, are interconnected by vias, such as vias 372, that may be characterized as part of the metallization layers or between the metallization layers. As shown, in some embodiments, metallization layers 320 are formed over and immediately adjacent circuit components 312. In the illustrated example, metallization layers 320 include M0, V0, M1, M2/V1, M3/V2, M4/V3, and M5-M7. However, metallization layers 320 may include any number of metallization layers such as eight or more metallization layers.

In one such embodiment, active layer 330 comprises a semiconductor layer 331 and circuit components 332 which are variously formed in or on semiconductor layer 331. Active layers 310, 330 are vertically stacked with each other—e.g., wherein metallization layers 320 and a portion of semiconductor layer 331 are disposed between circuit components 332 and active layer 310. In one such embodiment, metallization layers 340 include M0, M1, M2/V1, M3/V2, M4/V3, and M5-M7. However, metallization layers 340 may include any number of metallization layers such as eight or more metallization layers.

Metallization layers 320, and metallization layers 340 are variously embedded within dielectric materials 373, 374. In the example of FIG. 3, package-level interconnects 306 are provided on or over metallization layers 390 (which comprise layers FM0-FM3)—e.g., as bumps over a passivation layer 355. In some embodiments, IC die 302 is attached to a circuit board, a substrate, or any of various other suitable devices (not shown) by package-level interconnects 306. However, package-level interconnects 306 may be provided using any suitable interconnect structures such as bond pads, solder bumps, etc. Interconnectivity of some or all of circuit components 312, 332 (and other transistors, etc.), signal routing in a separation layer between channel stack structures, and routing to an outside device (not shown), is variously provided with some or all of metallization layers 320, metallization layers 340, metallization layers 390, package-level interconnects 306.

To facilitate electrical connectivity across multiple active layers, via structure 350 extends vertically through active layer 330—e.g., as well as through metallization layers 320 and at least one or more of metallization layers 340—and at least to a side 314 of active layer 310. By way of illustration and not limitation, via structure 350 extends through each of a side 314 of active layer 310, a vertical span of circuit components 312, and semiconductor layer 311, to an opposite side 316 where a dielectric layer 361 at least partially insulates active layer 310 from interconnect structures of metallization layers 390. In the example embodiment shown, a distal end of via structure 350 lands on a interconnect structure 360 of the metallization layer FM0. Accordingly, via structure 350 facilitates electrical coupling across multiple active layers including the illustrative active layers 310, 330 shown (e.g., wherein interconnect structure 360 is electrically coupled via via structure 350 to an interconnect structure 351 in the layer M7 of metallization layers 340).

In the example embodiment shown, a main body portion of via structure 350 tapers along a vertical (z-axis) distance between metallization layers 340 and side 314. By way of illustration and not limitation, horizontal (x-axis) length w1 of such a main body portion at layer M7 of metallization layers 340 differs by at least 10% from a corresponding length w2 of the main body portion at side 314.

In some embodiments, a width of via structure 350 in at least one metallization layer is at least five times (and in some embodiments, at least ten time) the width of another via structure which is within, or which adjoins, that same metallization layer. By way of illustration and not limitation, the width w2 of via structure 350 is at least five times the width of another via which is in (or alternatively, which adjoins) the layer M0 of metallization layers 320. Alternatively or in addition, a width of via structure 350 in the layer M0 of metallization layers 340 is at least five times a width of another via which is in (or alternatively, which adjoins) that same layer M0 of metallization layers 340.

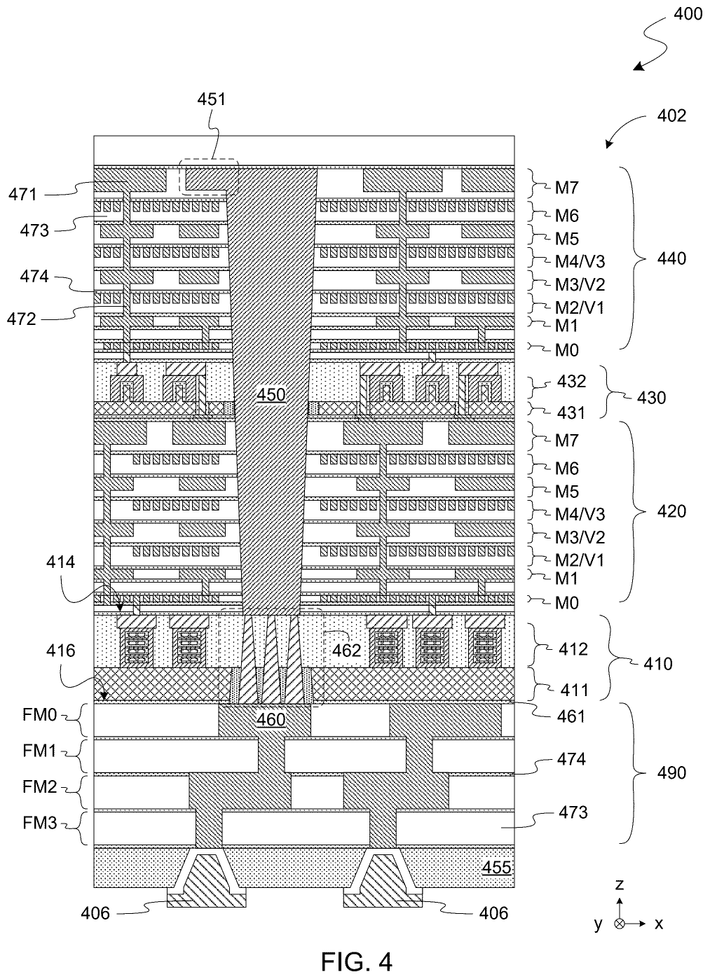

FIG. 4 shows features of an IC system 400 which facilitates electrical coupling across multiple active layers according to an embodiment. IC system 400 illustrates one example embodiment wherein a via structure, which extends through one active layer of an IC die, is electrically coupled to a plurality of vias which each extend through another active layer of the IC die. In various embodiments, IC system 400 provides functionality such as that of IC die structure 100 or of IC system 300—e.g., wherein structures of IC system 400 are provided by one or more operations of method 200.

As shown in FIG. 4, IC system 400 includes an IC die 402 which comprises multiple active layers and metallization layers which are variously disposed each between a respective two of the active layers, on a topmost one of the active layers, or under a bottommost one of the active layers. In the example embodiment shown, IC die 402 comprises active layers 410, 430, metallization layers 420, metallization layers 440, and metallization layers 490, which variously provide functionality such as that of active layers 310, 330, metallization layers 320, metallization layers 340, and metallization layers 390 (respectively). Active layer 410 comprises a semiconductor layer 411 and circuit components 412 which are variously formed in or on semiconductor layer 411. Furthermore, active layer 430 comprises a semiconductor layer 431 and circuit components 432 which are variously formed in or on semiconductor layer 431.

Metallization layers 420, metallization layers 440 and metallization layers 490 variously comprise respective metallization interconnects 471, vias 472, and/or other suitable interconnect structures, which are variously embedded within dielectric materials 473, 474. Additional electrical connectivity is facilitated, for example, with package-level interconnects 406 which are coupled to metallization layers 490 via a passivation layer 455.

Furthermore, IC die 402 comprises a via structure 450 which, for example, corresponds functionally to via structure 350. In the illustrative embodiment shown, a layer M7 of metallization layers 440 (for example) comprises an interconnect structure 451 which extends to be electrically coupled at the main body portion of via structure 450—e.g., to facilitate a delivery of power to circuitry of one or more of the active layers 410, 430. For example, via structure 450 extends vertically from interconnect structure 451 to a side 414 of active layer 410. A dielectric layer 461—at an opposite side 416 of active layer 410—provides at least partial insulation of circuit components 412 from one or more interconnect structures of metallization layers 490

In one such embodiment, a layer FM0 of the metallization layers 490 includes an interconnect structure 460 which is exposed by an opening of dielectric layer 461. Multiple vias 462 of IC system 400 variously extend each at least partially through active layer 410—e.g., between the opposite sides 414, 416 thereof—to electrically couple interconnect structure 460 a distal end of 450. In an embodiment, the combination of via structure 450 and the multiple vias 462 enables electrical coupling across active layer 410 and active layer 430—e.g., wherein interconnect structure 451 (and, for example, one or more other interconnect structures of metallization layers 420 and metallization layers 440) are coupled to provide a voltage and/or a signal with interconnect structure 460.

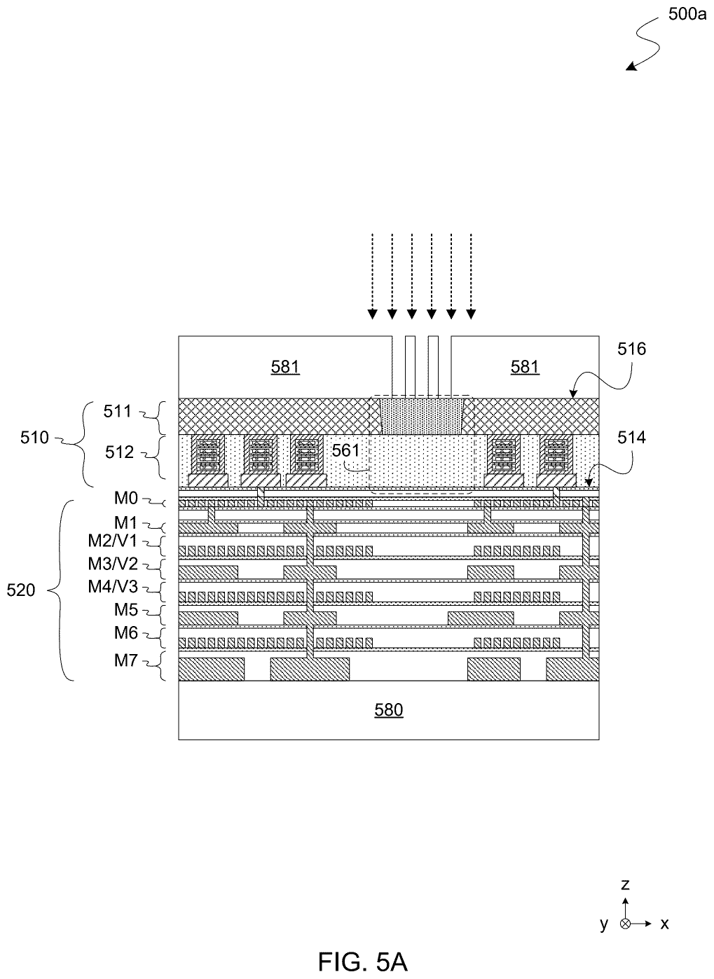

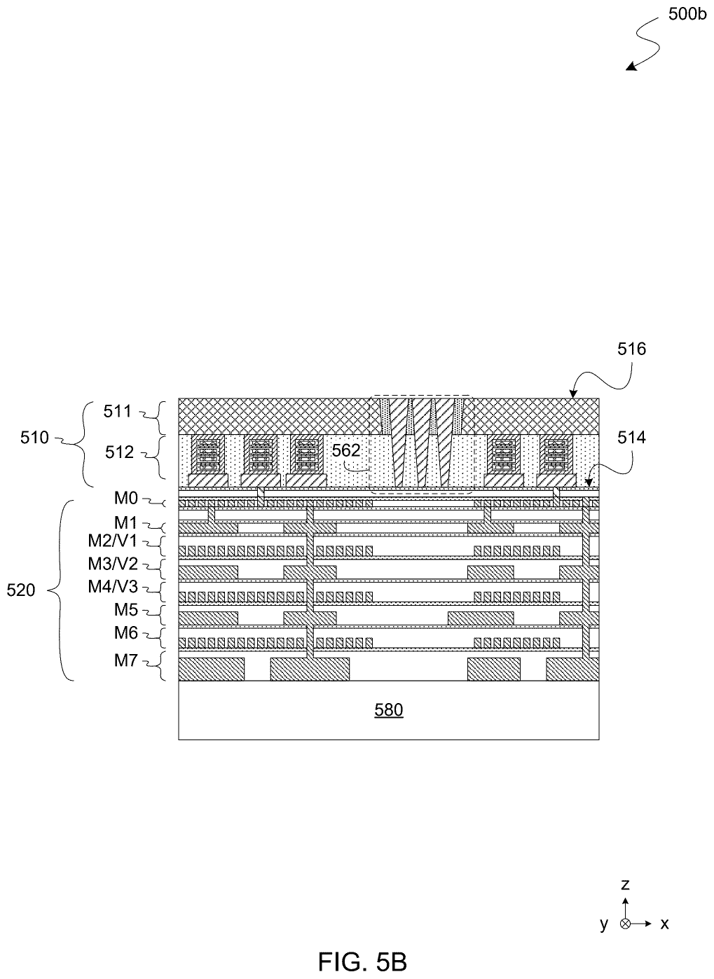

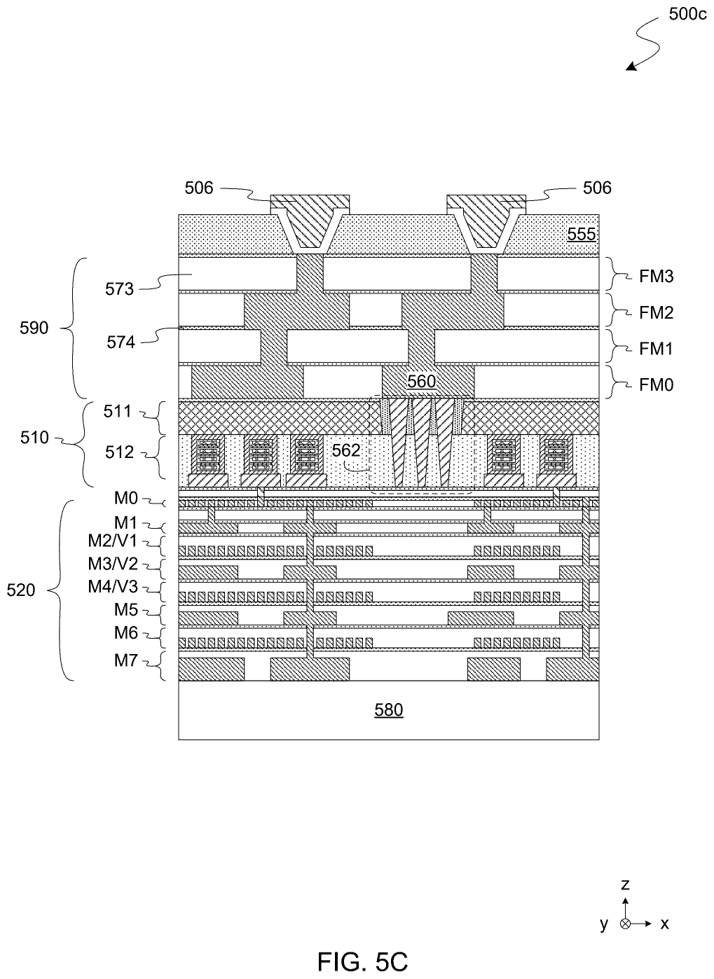

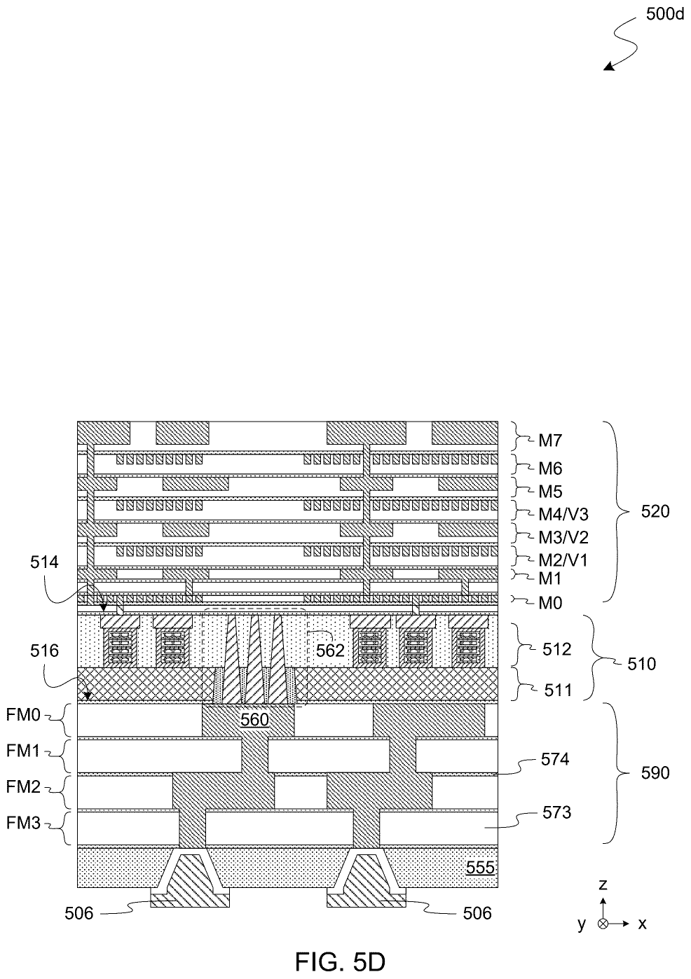

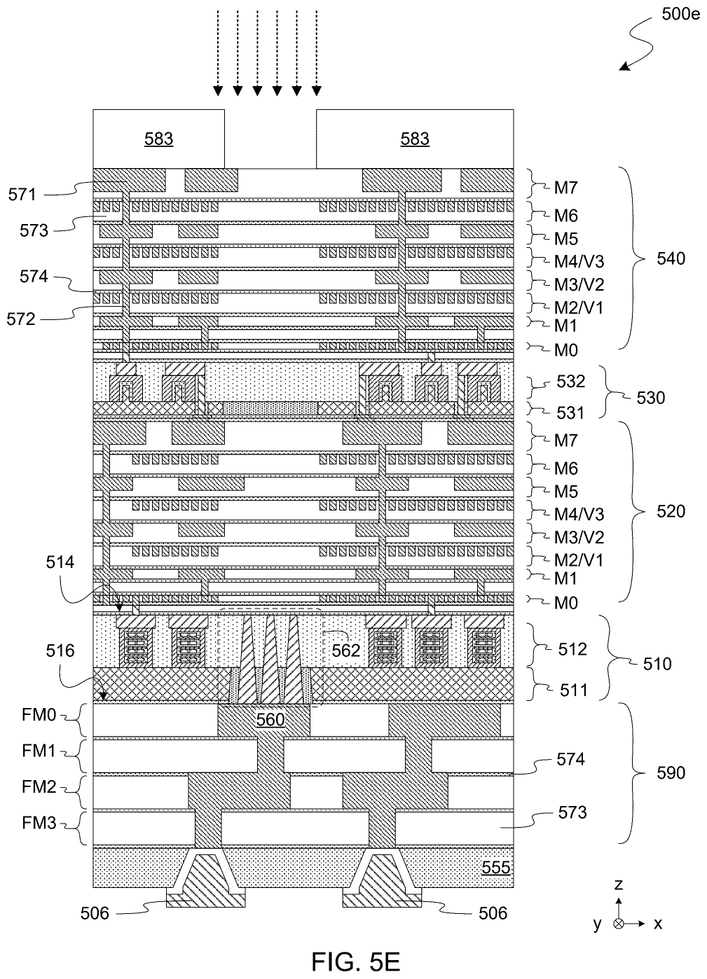

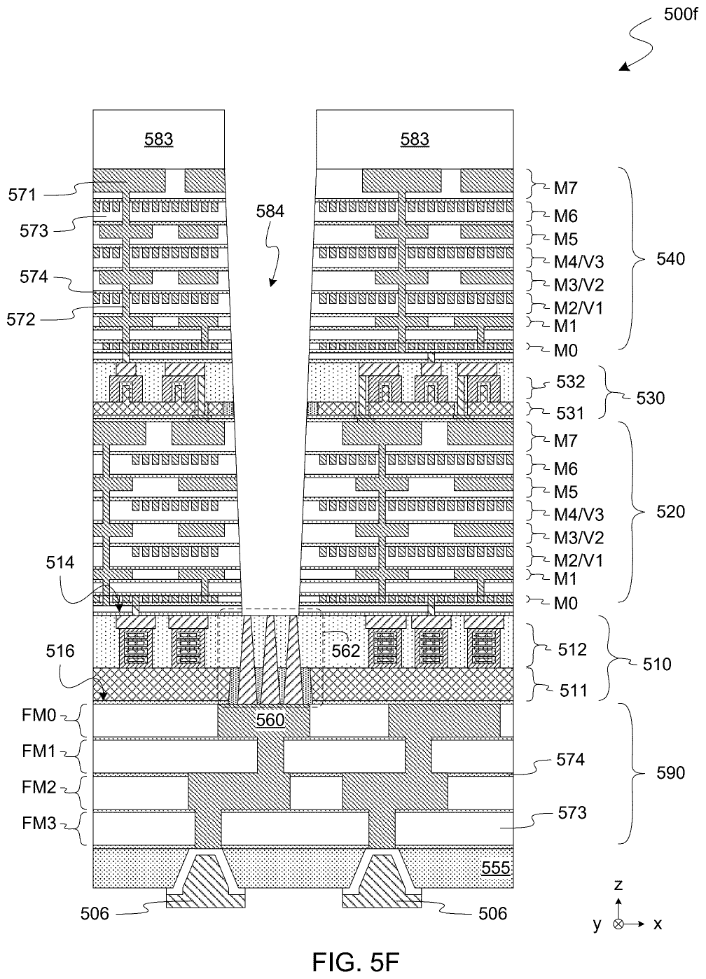

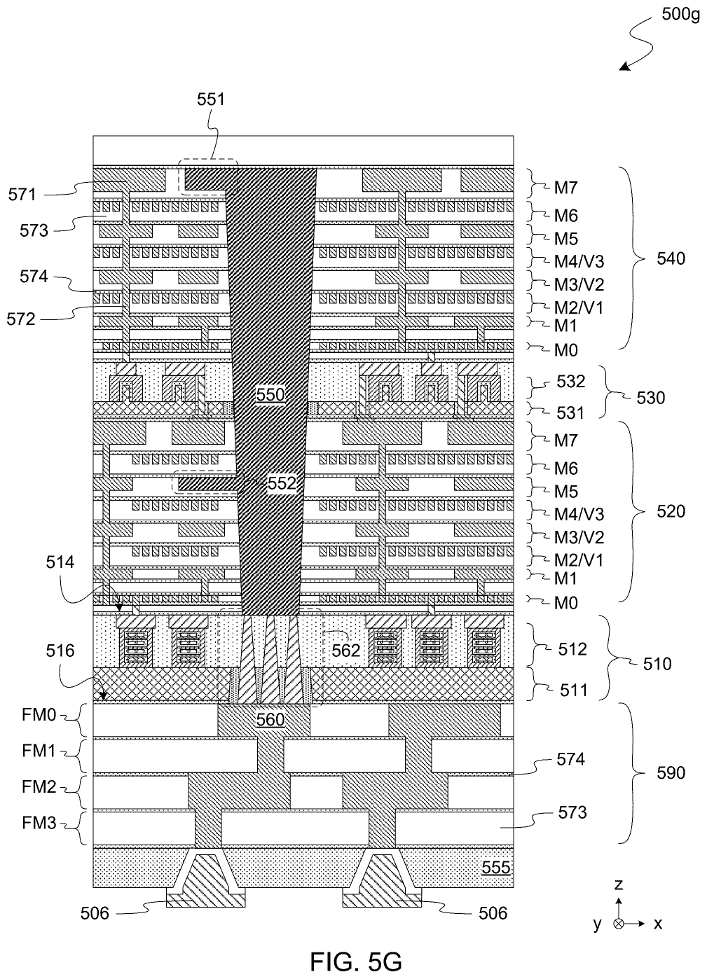

FIGS. 5A-5G show various cross-sectional side views of structures each during a respective one of multiple stages 500a through 500g of processing to fabricate an IC die structure according to an embodiment. In various embodiments, processing such as that illustrated by stages 500a through 500g provides circuitry of one of IC die structures 100, 300, 400 or the like—e.g., wherein said processing includes operations of method 200.

As shown in FIG. 5A, semiconductor processing has been performed, by stage 500a, to fabricate an active layer 510 comprising semiconductor layer 511 and circuit components 512, structures of which which are variously formed in or on semiconductor layer 511. Furthermore, patterned metal deposition processing has formed metallization layers 520 on a back end of active layer 510. By way of illustration and not limitation, active layer 510 has features of one of active layers 110, 410—e.g., wherein metallization layers 520 corresponds functionally to metallization layers 120 or metallization layers 420.

At some point during or after such semiconductor and metallization processing, a handling layer 580 is coupled to the combination of active layer 510 and metallization layers 520, which is then inverted to facilitate additional processing on a front side of active layer 510. In one such embodiment, etching through a patterned mask 581 is performed to selectively remove material from a region 561 in active layer 510. By way of illustration and not limitation, a plasma (and/or other) etch forms multiple through-hole structures which each extend between opposite sides 514, 516 of active layer 510. Subsequently, metal deposition processing is performed to form via structures each in a different respective one of said multiple through-hole structures. In an embodiment, such patterned etch and deposition processing includes operations which, for example, are adapted from any of various conventional techniques for forming through-silicon vias (and/or other through-substrate via structures).

For example, at the stage 500b shown in FIG. 5B, multiple vias 562 have been formed in the region 561 of active layer 510—e.g., wherein the multiple vias 562 variously extend vertically from side 516 of active layer 510 and at least partially toward the opposite side 514. In one such embodiment, the multiple vias 562 extend at least through semiconductor layer 511 (for example).

At the stage 500c shown in FIG. 5C, additional patterned metal deposition processing has been performed to provide, on a front end of active layer 510, metallization layers 590 comprising interconnect structures which are variously embedded within dielectric materials 573, 574. In various embodiments, one such interconnect structure 560—in a layer FM0 of the metallization layers 590—adjoins respective ends of each of the multiple vias 562 at side 516. Additional electrical connectivity is facilitated, for example, with the fabrication of package-level interconnects 506 which are coupled to metallization layers 590 via a passivation layer 555.

After fabrication of vias 562 and metallization layers 590, the circuit structures provided at stage 500c are inverted (and handling layer 580 is removed)—as illustrated by the stage 500d shown in FIG. 5D—to facilitate additional fabrication on a back end of active layer 510.

Referring now to FIG. 5E, at stage 500e semiconductor processing has been performed to fabricate an active layer 530 comprising semiconductor layer 531 and circuit components 532 which are variously formed therein or thereon. Furthermore, patterned metal deposition processing has formed metallization layers 540 on a back end of active layer 530. Metallization layers 520, metallization layers 540 and metallization layers 590 variously comprise respective metallization interconnects 571, vias 572, and/or other suitable interconnect structures, which are variously embedded within dielectric materials 573, 574. By way of illustration and not limitation, active layer 530 has features of one of active layers 130, 430—e.g., wherein metallization layers 540 corresponds functionally to metallization layers 140 or metallization layers 440.

Subsequently, a patterned mask 583 is formed on metallization layers 540, and one or more etch processes are performed to selectively remove respective portions of at least metallization layers 540, active layer 530, and metallization layers 520. For example, at the stage 500f shown in FIG. 5F, etch processing has formed a recess structure 584 which exposes respective ends of the multiple vias 562—e.g., wherein recess structure 584 extends through metallization layers 540, active layer 530, and metallization layers 520 to side 514 of active layer 510. In some embodiments, formation of recess structure 584 comprises any of various wet etch operations and/or dry etch operations which (for example) are adapted from conventional subtractive processing techniques.

At the stage 500g shown in FIG. 5G, metal deposition processing has formed in recess structure 584 a via structure 550 which extends to the respective ends of multiple vias 562. In some embodiments, one or more interconnect structures of metallization layers 540 (and, in some embodiments, one or more interconnect structures of metallization layers 520) are exposed by the formation of recess structure 584. Therefore, metal deposition into recess structure 584 results in via structure 550 extending to—and being electrically coupled with—some or all such exposed one or more interconnect structures.

In the example embodiment shown, via structure 550 is electrically coupled to an interconnect structure 551 which is in a layer M7 of the metallization layers 540. Furthermore, via structure 550 is electrically coupled to another interconnect structure 552 which is in a layer M5 of the metallization layers 520. In one such embodiment, via structure 550 (in combination with the multiple vias 562) facilitates electrical coupling of interconnect structure 560 with interconnect structures 551, 552—i.e., where said electrical coupling is variously across some or all of active layer 510, metallization layers 520, active layer 530, and one or more of metallization layers 540.

In various embodiments, a main body portion of via structure 550 is substantially tapered between interconnect structure 551 and side 514—e.g., wherein a (x-dimension) width of via structure 550 decreases along a first vertical (z-axis) direction. By contrast, some or all of the multiple vias 562 are each substantially tapered between side 516 and side 514—e.g., wherein respective widths of the multiple vias 562 variously decrease each along a second vertical direction which is opposite the first vertical direction.

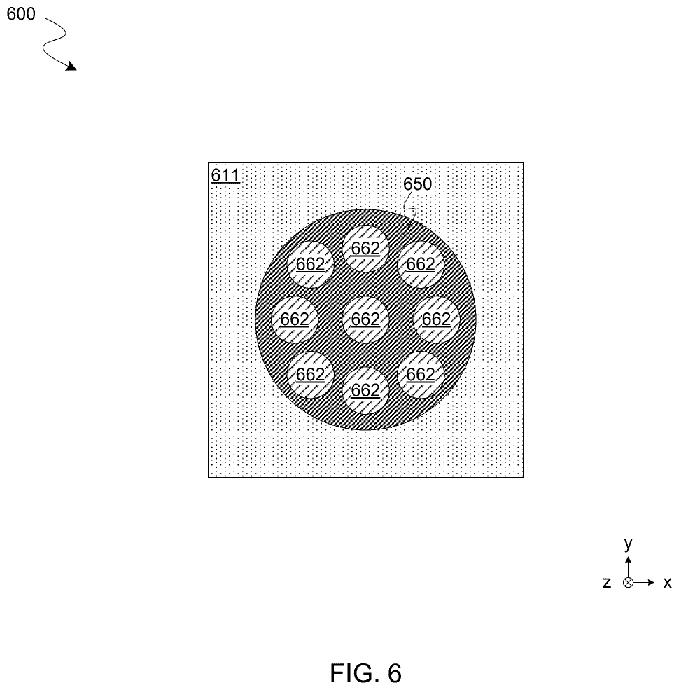

FIG. 6 shows a cross-sectional view diagram illustrating features of an IC die structure 600 according to an embodiment. IC die structure 600 illustrates features of one example embodiment wherein via structures adjoin each other to facilitate electrical coupling across multiple active layers of an IC die. In some embodiments, IC die structure 600 provides functionality such as that of IC die 402—e.g., wherein operations of method 200 provide structures of IC die structure 600.

In FIG. 6, features of IC die structure 600 are shown in a horizontal (x-y) plane such as that at the side 414 of active layer 410 or, for example, at the side 514 of active layer 510. In the example embodiment shown, a via structure 650 extends in a vertical (z-axis) direction at least to a side of, but not into—or at least not entirely through—a first active layer such as one of active layers 110, 310, 410, 510. The via structure 650 has features of one of via structures 150, 450 550, for example.

In an embodiment, a material 611 of the first active layer—e.g., a dielectric material or, alternatively, a semiconductor material—is in a horizontal plane at which a plurality of vias 662 variously meet a distal end of via structure 650. The plurality of vias 662 each extend from a first interconnect structure (e.g., one of interconnect structures 162, 360, 460, 560), and at least partially through the first active layer, to a distal end of via structure 650. Although IC die structure 600 is shown as including nine vias 662 which couple to via structure 650 in the horizontal plane, some embodiments have more, fewer, differently sized and/or differently arranged vias which extend to via structure 650. In one such embodiment, a total of the respective cross-sectional areas of the plurality of vias 662 in the horizontal plane is at least one third (and in some embodiments, at least one half) of a contiguous cross-sectional area of via structure 650 in that horizontal plane.

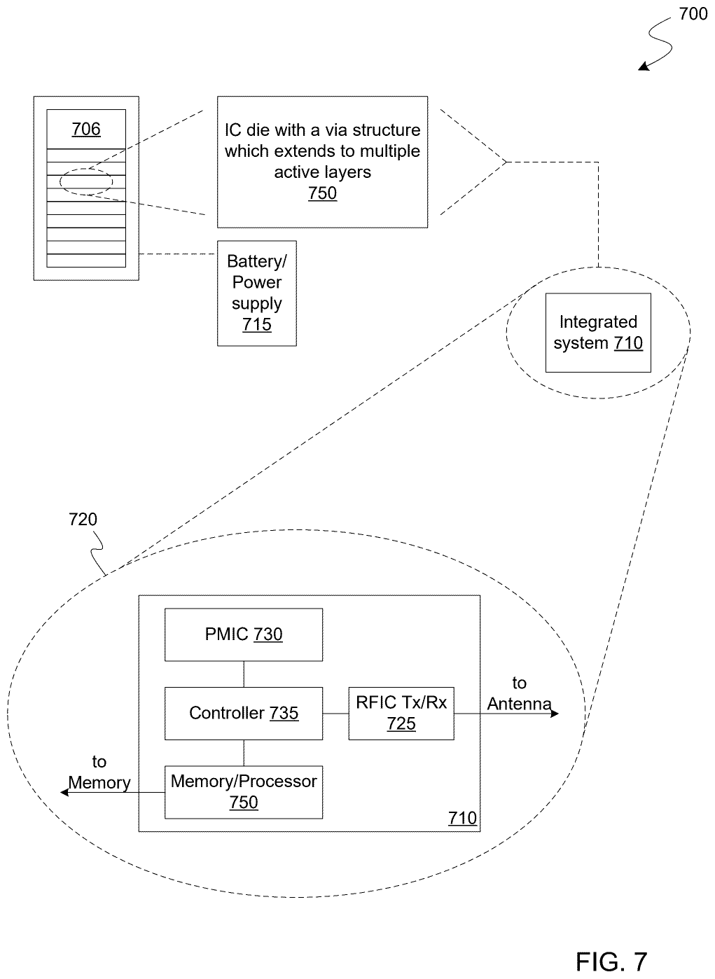

FIG. 7 illustrates a diagram of an example system 700 comprising a data server machine 706 which employs an IC die comprising a via structure which extends to each of multiple active layers, in accordance with some embodiments. Server machine 706 may be any commercial server, for example, including any number of high-performance computing platforms disposed within a rack and networked together for electronic data processing, which in the exemplary embodiment includes one or more devices 750 each having a respective via structure which facilitates electrical coupling across multiple active layers.

Also as shown, server machine 706 includes a battery and/or power supply 715 to provide power to devices 750, and to provide, in some embodiments, power delivery functions such as power regulation. Devices 750 may be deployed as part of a package-level integrated system 710. Integrated system 710 is further illustrated in the expanded view 720. In the exemplary embodiment, devices 750 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 750 is a microprocessor of an IC die which comprises multiple active layers and a via structure which extends through one such active layer, and which spans metallization layers between said active layers. As shown, device 750 may be a multi-chip module employing one or more IC dies which each comprise a respective via structure, as described herein. Device 750 may be further coupled to (e.g., communicatively coupled to) a board, an interposer, or a substrate along with, one or more of a power management IC (PMIC) 730, RF (wireless) IC (RFIC) 725, including a wideband RF (wireless) transmitter and/or receiver (TX/RX) (e.g., including a digital baseband and an analog front end module further comprises a power amplifier on a transmit path and a low noise amplifier on a receive path), and a controller 735 thereof. In some embodiments, RFIC 725, PMIC 730, controller 735, and device 750 include IC dies having respective via structures in a multi-chip module.

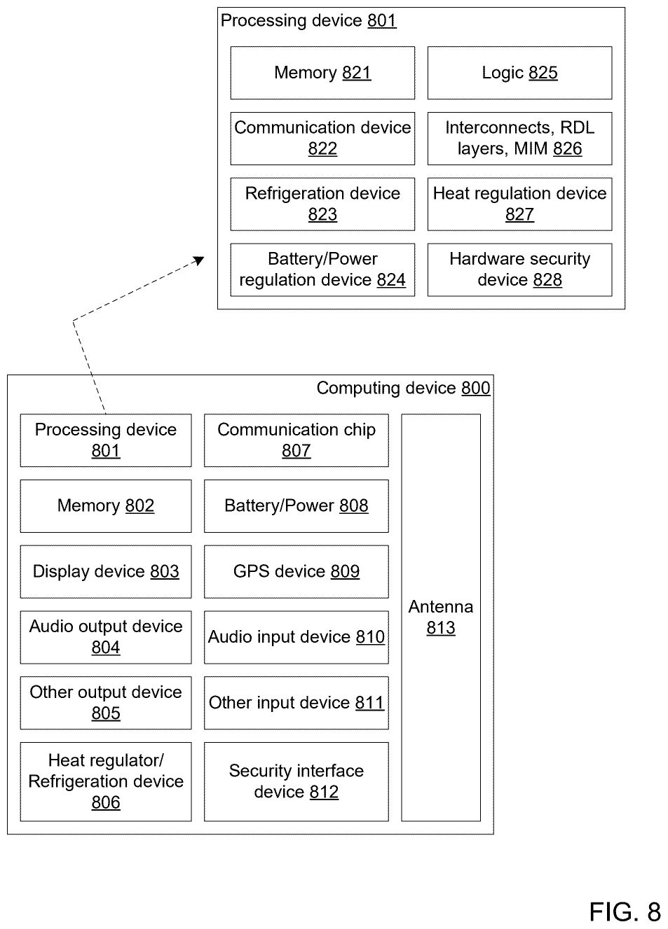

FIG. 8 is a block diagram of an example computing device 800, in accordance with some embodiments. For example, one or more components of computing device 800 may include any of the devices or structures discussed herein. A number of components are illustrated in FIG. 8 as being included in computing device 800, but any one or more of these components may be omitted or duplicated, as suitable for the application. In some embodiments, some or all of the components included in computing device 800 may be attached to one or more printed circuit boards (e.g., a motherboard). In some embodiments, various ones of these components may be fabricated onto a single system-on-a-chip (SoC) die. Additionally, in various embodiments, computing device 800 may not include one or more of the components illustrated in FIG. 8, but computing device 800 may include interface circuitry for coupling to the one or more components. For example, computing device 800 may not include a display device 803, but may include display device interface circuitry (e.g., a connector and driver circuitry) to which display device 803 may be coupled. In another set of examples, computing device 800 may not include an audio output device 804, other output device 805, global positioning system (GPS) device 809, audio input device 810, or other input device 811, but may include audio output device interface circuitry, other output device interface circuitry, GPS device interface circuitry, audio input device interface circuitry, audio input device interface circuitry, to which audio output device 804, other output device 805, GPS device 809, audio input device 810, or other input device 811 may be coupled.

Computing device 800 may include a processing device 801 (e.g., one or more processing devices). As used herein, the term “processing device” or “processor” indicates a device that processes electronic data from registers and/or memory (such as SRAM) to transform that electronic data into other electronic data that may be stored in registers and/or memory (e.g., SRAM). Processing device 801 may include a memory 821 (itself including SRAM), a communication device 822, a refrigeration device 823, a battery/power regulation device 824, logic 825, interconnects 826 (i.e., optionally including redistribution layers (RDL) or metal-insulator-metal (MIM) devices), a heat regulation device 827, and a hardware security device 828.

Processing device 801 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 800 may include a memory 802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 802 includes memory that shares a die with processing device 801. This memory may be used as cache memory and may include embedded dynamic random-access memory (eDRAM) or spin transfer torque magnetic random-access memory (STT-M RAM).

Computing device 800 may include a heat regulation/refrigeration device 806. Heat regulation/refrigeration device 806 may maintain processing device 801 (and/or other components of computing device 800) at a predetermined low temperature during operation. This predetermined low temperature may be any temperature discussed herein.

In some embodiments, computing device 800 may include a communication chip 807 (e.g., one or more communication chips). For example, the communication chip 807 may be configured for managing wireless communications for the transfer of data to and from computing device 800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 807 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 807 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 807 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 807 may operate in accordance with other wireless protocols in other embodiments. Computing device 800 may include an antenna 813 to facilitate wireless communications and/or to receive other wireless communications (such as AM or FM radio transmissions).

In some embodiments, communication chip 807 may manage wired communications, such as electrical, optical, or any other suitable communication protocols (e.g., the Ethernet). As noted above, communication chip 807 may include multiple communication chips. For instance, a first communication chip 807 may be dedicated to shorter-range wireless communications such as Wi-Fi or Bluetooth, and a second communication chip 807 may be dedicated to longer-range wireless communications such as GPS, EDGE, GPRS, CDMA, WiMAX, LTE, EV-DO, or others. In some embodiments, a first communication chip 807 may be dedicated to wireless communications, and a second communication chip 807 may be dedicated to wired communications.

Computing device 800 may include battery/power circuitry 808. Battery/power circuitry 808 may include one or more energy storage devices (e.g., batteries or capacitors) and/or circuitry for coupling components of computing device 800 to an energy source separate from computing device 800 (e.g., AC line power).

Computing device 800 may include a display device 803 (or corresponding interface circuitry, as discussed above). Display device 803 may include any visual indicators, such as a heads-up display, a computer monitor, a projector, a touchscreen display, a liquid crystal display (LCD), a light-emitting diode display, or a flat panel display, for example.

Computing device 800 may include an audio output device 804 (or corresponding interface circuitry, as discussed above). Audio output device 804 may include any device that generates an audible indicator, such as speakers, headsets, or earbuds, for example.

Computing device 800 may include an audio input device 810 (or corresponding interface circuitry, as discussed above). Audio input device 810 may include any device that generates a signal representative of a sound, such as microphones, microphone arrays, or digital instruments (e.g., instruments having a musical instrument digital interface (MIDI) output).

Computing device 800 may include a GPS device 809 (or corresponding interface circuitry, as discussed above). GPS device 809 may be in communication with a satellite-based system and may receive a location of computing device 800, as known in the art.

Computing device 800 may include other output device 805 (or corresponding interface circuitry, as discussed above). Examples of the other output device 805 may include an audio codec, a video codec, a printer, a wired or wireless transmitter for providing information to other devices, or an additional storage device.

Computing device 800 may include other input device 811 (or corresponding interface circuitry, as discussed above). Examples of the other input device 811 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 800 may include a security interface device 812. Security interface device 812 may include any device that provides security measures for computing device 800 such as intrusion detection, biometric validation, security encode or decode, access list management, malware detection, or spyware detection.

Computing device 800, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

In one or more first embodiments, an integrated circuit (IC) die structure comprises first metallization layers comprising a first interconnect structure, a first active layer comprising first circuit components, a second active layer comprising second circuit components, second metallization layers between the first active layer and the second active layer, wherein the first active layer is between the first metallization layers and the second metallization layers, third metallization layers comprising a second interconnect structure, wherein the second active layer is between the second metallization layers and the third metallization layers, and a via structure which extends from the second interconnect structure, through one or more of the third metallization layers, and further through each of the second active layer and the second metallization layers, to a first side of the first active layer, wherein the via structure is electrically coupled to each of the first interconnect structure and the second interconnect structure.

In one or more second embodiments, further to the first embodiment, the via structure extends through the first active layer to the first interconnect structure.

In one or more third embodiments, further to the second embodiment, the via structure adjoins the first interconnect structure in a first plane, and a first total cross-sectional area of the via structure is less than eighty percent of a second total cross-sectional area of the first interconnect structure in the first plane.

In one or more fourth embodiments, further to the first embodiment or the second embodiment, the second metallization layers comprise a third interconnect structure which extends to the via structure, and the via structure electrically couples the first interconnect structure, the second interconnect structure, and the third interconnect structure to each other.

In one or more fifth embodiments, further to the first embodiment or the second embodiment, the IC die structure further comprises multiple vias which each extend from the first interconnect structure, and at least partially through the first active layer, to a distal end of the via structure.

In one or more sixth embodiments, further to the fifth embodiment, the via structure adjoins each of the multiple vias in a first plane, and a first total cross-sectional area of all of the multiple vias in the first plane is at least one third of a second total cross-sectional area of the via structure in the first plane.

In one or more seventh embodiments, further to the fifth embodiment, a first horizontal width of the via structure tapers along a first vertical direction, and for via each of the multiple vias, a respective horizontal width of the via tapers along a second vertical direction which is opposite the first vertical direction.

In one or more eighth embodiments, further to the first embodiment or the second embodiment, the via structure is a first via structure, the first metallization layers further comprise a third interconnect structure, the third metallization layers further comprise a fourth interconnect structure, and the IC die structure further comprises a second via structure which extends from the fourth interconnect structure, through another one or more of the third metallization layers, and further through each of the second active layer and the second metallization layers, to the first side of the first active layer, wherein the second via structure is electrically coupled to each of the third interconnect structure and the fourth interconnect structure.

In one or more ninth embodiments, further to the first embodiment or the second embodiment, the IC die structure further comprises a third active layer between the second metallization layers and the second active layer, the third active layer comprising third circuit components, and fourth metallization layers between the third active layer and the third metallization layers, wherein the via structure further extends through the third active layer and through each of the fourth metallization layers.

In one or more tenth embodiments, a method, for fabricating an integrated circuit (IC) die structure, comprises forming first metallization layers which comprise a first interconnect structure, forming a first active layer which comprise first circuit components, forming second metallization layers on the first active layer, wherein the first active layer is between the first metallization layers and the second metallization layers, forming a second active layer which comprise second circuit components, wherein the second metallization layers are between the first active layer and the second active layer, forming third metallization layers which comprise a second interconnect structure, wherein the second active layer is between the second metallization layers and the third metallization layers, and forming a via structure which extends from the second interconnect structure, through one or more of the third metallization layers, and further through each of the second active layer and the second metallization layers, to a first side of the first active layer, wherein the via structure is electrically coupled to each of the first interconnect structure and the second interconnect structure.

In one or more eleventh embodiments, further to the tenth embodiment, the via structure extends through the first active layer to the first interconnect structure.

In one or more twelfth embodiments, further to the eleventh embodiment, the via structure adjoins the first interconnect structure in a first plane, and a first total cross-sectional area of the via structure is less than eighty percent of a second total cross-sectional area of the first interconnect structure in the first plane.

In one or more thirteenth embodiments, further to the tenth embodiment or the eleventh embodiment, forming the second metallization layers comprises forming a third interconnect structure, and the via structure electrically couples the first interconnect structure, the second interconnect structure, and the third interconnect structure to each other.

In one or more fourteenth embodiments, further to the tenth embodiment or the eleventh embodiment, the method further comprises forming multiple vias which each extend from the first interconnect structure, and at least partially through the first active layer, to a distal end of the via structure.

In one or more fifteenth embodiments, further to the fourteenth embodiment, the via structure adjoins each of the multiple vias in a first plane, and a first total cross-sectional area of all of the multiple vias in the first plane is at least one third of a second total cross-sectional area of the via structure in the first plane.

In one or more sixteenth embodiments, further to the fourteenth embodiment, a first horizontal width of the via structure tapers along a first vertical direction, and for via each of the multiple vias, a respective horizontal width of the via tapers along a second vertical direction which is opposite the first vertical direction.

In one or more seventeenth embodiments, further to the tenth embodiment or the eleventh embodiment, the via structure is a first via structure, the first metallization layers further comprise a third interconnect structure, the third metallization layers further comprise a fourth interconnect structure, and the method further comprises forming a second via structure which extends from the fourth interconnect structure, through another one or more of the third metallization layers, and further through each of the second active layer and the second metallization layers, to the first side of the first active layer, wherein the second via structure is electrically coupled to each of the third interconnect structure and the fourth interconnect structure.

In one or more eighteenth embodiments, further to the tenth embodiment or the eleventh embodiment, the method further comprises forming a third active layer between the second metallization layers and the second active layer, the third active layer comprising third circuit components, and forming fourth metallization layers between the third active layer and the third metallization layers, wherein the via structure further extends through the third active layer and through each of the fourth metallization layers.

In one or more nineteenth embodiments, a system comprises an integrated circuit (IC) die comprising first metallization layers comprising a first interconnect structure, a first active layer comprising first circuit components, a second active layer comprising second circuit components, second metallization layers between the first active layer and the second active layer, wherein the first active layer is between the first metallization layers and the second metallization layers, third metallization layers comprising a second interconnect structure, wherein the second active layer is between the second metallization layers and the third metallization layers, and a via structure which extends from the second interconnect structure, through one or more of the third metallization layers, and further through each of the second active layer and the second metallization layers, to a first side of the first active layer, wherein the via structure is electrically coupled to each of the first interconnect structure and the second interconnect structure, and a display device coupled to the IC die, the display device to display an image based on a voltage or a signal which is provided with the via structure.

In one or more twentieth embodiments, further to the nineteenth embodiment, the via structure extends through the first active layer to the first interconnect structure.

In one or more twenty-first embodiments, further to the ‘0 embodiment, the via structure adjoins the first interconnect structure in a first plane, and a first total cross-sectional area of the via structure is less than eighty percent of a second total cross-sectional area of the first interconnect structure in the first plane.

In one or more twenty-second embodiments, further to the nineteenth embodiment or the twentieth embodiment, the second metallization layers comprise a third interconnect structure which extends to the via structure, and the via structure electrically couples the first interconnect structure, the second interconnect structure, and the third interconnect structure to each other.

In one or more twenty-third embodiments, further to the nineteenth embodiment or the twentieth embodiment, the IC die further comprises multiple vias which each extend from the first interconnect structure, and at least partially through the first active layer, to a distal end of the via structure.

In one or more twenty-fourth embodiments, further to the twenty-third embodiment, the via structure adjoins each of the multiple vias in a first plane, and a first total cross-sectional area of all of the multiple vias in the first plane is at least one third of a second total cross-sectional area of the via structure in the first plane.

In one or more twenty-fifth embodiments, further to the twenty-third embodiment, a first horizontal width of the via structure tapers along a first vertical direction, and for via each of the multiple vias, a respective horizontal width of the via tapers along a second vertical direction which is opposite the first vertical direction.

In one or more twenty-sixth embodiments, further to the nineteenth embodiment or the twentieth embodiment, the via structure is a first via structure, the first metallization layers further comprise a third interconnect structure, the third metallization layers further comprise a fourth interconnect structure, and the IC die further comprises a second via structure which extends from the fourth interconnect structure, through another one or more of the third metallization layers, and further through each of the second active layer and the second metallization layers, to the first side of the first active layer, wherein the second via structure is electrically coupled to each of the third interconnect structure and the fourth interconnect structure.

In one or more twenty-seventh embodiments, further to the nineteenth embodiment or the twentieth embodiment, the IC die further comprises a third active layer between the second metallization layers and the second active layer, the third active layer comprising third circuit components, and fourth metallization layers between the third active layer and the third metallization layers, wherein the via structure further extends through the third active layer and through each of the fourth metallization layers.

Techniques and architectures for electrically coupling integrated circuitry are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. An integrated circuit (IC) die structure comprising:
first metallization layers comprising a first interconnect structure;
a first active layer comprising first circuit components;
a second active layer comprising second circuit components;
second metallization layers between the first active layer and the second active layer, wherein the first active layer is between the first metallization layers and the second metallization layers;
third metallization layers comprising a second interconnect structure, wherein the second active layer is between the second metallization layers and the third metallization layers; and
a via structure which extends from the second interconnect structure, through one or more of the third metallization layers, and further through each of the second active layer and the second metallization layers, to a first side of the first active layer, wherein the via structure is electrically coupled to each of the first interconnect structure and the second interconnect structure.

2. The IC die structure of claim 1, wherein the via structure extends through the first active layer to the first interconnect structure.

3. The IC die structure of claim 2, wherein:
the via structure adjoins the first interconnect structure in a first plane; and
a first total cross-sectional area of the via structure is less than eighty percent of a second total cross-sectional area of the first interconnect structure in the first plane.

4. The IC die structure of claim 1, wherein:
the second metallization layers comprise a third interconnect structure which extends to the via structure; and
the via structure electrically couples the first interconnect structure, the second interconnect structure, and the third interconnect structure to each other.

5. The IC die structure of claim 1, further comprising:
multiple vias which each extend from the first interconnect structure, and at least partially through the first active layer, to a distal end of the via structure.

6. The IC die structure of claim 5, wherein:
the via structure adjoins each of the multiple vias in a first plane; and
a first total cross-sectional area of all of the multiple vias in the first plane is at least one third of a second total cross-sectional area of the via structure in the first plane.

7. The IC die structure of claim 5, wherein:
a first horizontal width of the via structure tapers along a first vertical direction; and
for via each of the multiple vias, a respective horizontal width of the via tapers along a second vertical direction which is opposite the first vertical direction.

8. The IC die structure of claim 1, wherein:
the via structure is a first via structure;
the first metallization layers further comprise a third interconnect structure;
the third metallization layers further comprise a fourth interconnect structure; and
the IC die structure further comprises a second via structure which extends from the fourth interconnect structure, through another one or more of the third metallization layers, and further through each of the second active layer and the second metallization layers, to the first side of the first active layer, wherein the second via structure is electrically coupled to each of the third interconnect structure and the fourth interconnect structure.

9. The IC die structure of claim 1, further comprising:
a third active layer between the second metallization layers and the second active layer, the third active layer comprising third circuit components; and
fourth metallization layers between the third active layer and the third metallization layers;
wherein the via structure further extends through the third active layer and through each of the fourth metallization layers.

10. A method for fabricating an integrated circuit (IC) die structure, the method comprising:
forming first metallization layers which comprise a first interconnect structure;
forming a first active layer which comprise first circuit components;
forming second metallization layers on the first active layer, wherein the first active layer is between the first metallization layers and the second metallization layers;
forming a second active layer which comprise second circuit components, wherein the second metallization layers are between the first active layer and the second active layer;
forming third metallization layers which comprise a second interconnect structure, wherein the second active layer is between the second metallization layers and the third metallization layers; and
forming a via structure which extends from the second interconnect structure, through one or more of the third metallization layers, and further through each of the second active layer and the second metallization layers, to a first side of the first active layer, wherein the via structure is electrically coupled to each of the first interconnect structure and the second interconnect structure.

11. The method of claim 10, wherein the via structure extends through the first active layer to the first interconnect structure.

12. The method of claim 10, wherein:
forming the second metallization layers comprises forming a third interconnect structure; and
the via structure electrically couples the first interconnect structure, the second interconnect structure, and the third interconnect structure to each other.

13. The method of claim 10, further comprising:
forming multiple vias which each extend from the first interconnect structure, and at least partially through the first active layer, to a distal end of the via structure.

14. The method of claim 13, wherein:
the via structure adjoins each of the multiple vias in a first plane; and
a first total cross-sectional area of all of the multiple vias in the first plane is at least one third of a second total cross-sectional area of the via structure in the first plane.

15. A system comprising:
an integrated circuit (IC) die comprising:
first metallization layers comprising a first interconnect structure;
a first active layer comprising first circuit components;
a second active layer comprising second circuit components;
second metallization layers between the first active layer and the second active layer, wherein the first active layer is between the first metallization layers and the second metallization layers;
third metallization layers comprising a second interconnect structure, wherein the second active layer is between the second metallization layers and the third metallization layers; and
a via structure which extends from the second interconnect structure, through one or more of the third metallization layers, and further through each of the second active layer and the second metallization layers, to a first side of the first active layer, wherein the via structure is electrically coupled to each of the first interconnect structure and the second interconnect structure; and
a display device coupled to the IC die, the display device to display an image based on a voltage or a signal which is provided with the via structure.

16. The system of claim 15, wherein the via structure extends through the first active layer to the first interconnect structure.

17. The system of claim 15, wherein:
the second metallization layers comprise a third interconnect structure which extends to the via structure; and
the via structure electrically couples the first interconnect structure, the second interconnect structure, and the third interconnect structure to each other.

18. The system of claim 15, further comprising:
multiple vias which each extend from the first interconnect structure, and at least partially through the first active layer, to a distal end of the via structure.

19. The system of claim 18, wherein:
the via structure adjoins each of the multiple vias in a first plane; and
a first total cross-sectional area of all of the multiple vias in the first plane is at least one third of a second total cross-sectional area of the via structure in the first plane.

20. The system of claim 18, wherein:
a first horizontal width of the via structure tapers along a first vertical direction; and
for via each of the multiple vias, a respective horizontal width of the via tapers along a second vertical direction which is opposite the first vertical direction.
